(19) United States
(12) Patent Application Publication
(10) Pub. No.: US 2026/0248011 A1
(43) Pub. Date: Aug. 20, 2026

(54) LIQUID COOLING MODULE

(71) Applicant: Taiwan Semiconductor Manufacturing Company Limited, Hsin-Chu (TW)

(72) Inventors: Sung-Ju HUANG, Taipei City (TW); Yung-Tsun LIU, Taipei City (TW); Kuang-Wei CHENG, Hsinchu City (TW)

(21) Appl. No.: 19/054,968

(22) Filed: Feb. 17, 2025

(51) Int. Cl. H01L 23/00

(52) U.S. Cl. CPC H10W 72/011; H10W 99/00; H10W 72/071; H10W 72/90; H10W 80/102; H10W 80/301; H10W 80/312; H10W 80/334; H10W 90/796

(57) ABSTRACT

An apparatus is provided. The apparatus includes a first platform configured to support a plurality of items to be bonded together in a bonding process. The apparatus includes a second platform over the plurality of items. At least one of the first platform or the second platform is configured to apply a pressing force to the plurality of items during the bonding process. The apparatus includes a liquid cooling module configured to conduct, after the bonding process, a liquid through a cooling channel to cool at least one of the first platform or the second platform.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagram depicting an apparatus, in accordance with some embodiments.

FIG. 2A illustrates a diagram depicting an apparatus in a scenario in which the apparatus is used to perform bonding processes, in accordance with some embodiments.

FIG. 2B illustrates a diagram depicting an apparatus in a scenario in which the apparatus is used to perform bonding processes, in accordance with some embodiments.

FIG. 2C illustrates a diagram depicting an apparatus in a scenario in which the apparatus is used to perform bonding processes, in accordance with some embodiments.

FIG. 2D illustrates a diagram depicting an apparatus in a scenario in which the apparatus is used to perform bonding processes, in accordance with some embodiments.

FIG. 2E illustrates a diagram depicting an apparatus in a scenario in which the apparatus is used to perform bonding processes, in accordance with some embodiments.

FIG. 2F illustrates a diagram depicting an apparatus in a scenario in which the apparatus is used to perform bonding processes, in accordance with some embodiments.

FIG. 2G illustrates a diagram depicting an apparatus in a scenario in which the apparatus is used to perform bonding processes, in accordance with some embodiments.

FIG. 2H illustrates a diagram depicting an apparatus in a scenario in which the apparatus is used to perform bonding processes, in accordance with some embodiments.

FIG. 3A illustrates a perspective view of a liquid cooling module, in accordance with some embodiments.

FIG. 3B illustrates a perspective view of a liquid cooling module without a first surface to show a conduit defining a cooling channel, in accordance with some embodiments.

FIG. 3C illustrates a schematic diagram of a liquid cooling module, in accordance with some embodiments.

FIG. 3D illustrates a view of a portion of a peripheral wall of a cooling module housing, in accordance with some embodiments.

FIG. 3E illustrates a top view of a conduit relative to a peripheral wall of a cooling module housing, in accordance with some embodiments.

FIG. 3F illustrates a top view of a conduit relative to a peripheral wall of a cooling module housing, in accordance with some embodiments.

FIG. 3G illustrates a top view of a conduit relative to a peripheral wall of a cooling module housing, in accordance with some embodiments.

FIG. 3H illustrates a top view of a conduit relative to a peripheral wall of a cooling module housing, in accordance with some embodiments.

FIG. 4 illustrates a graph associated with a cooling process, in accordance with some embodiments.

FIG. 5 illustrates a cross-sectional view of a semiconductor device, in accordance with some embodiments.

FIG. 6 is a flow diagram illustrating a method, in accordance with some embodiments.

FIG. 7 illustrates an example computer-readable medium wherein processor-executable instructions configured to embody one or more of the provisions set forth herein may be comprised, in accordance with some embodiments.

### DETAILED DESCRIPTION

The following disclosure provides several different embodiments, or examples, for implementing different features of the provided subject matter.

Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

A bonding apparatus includes a first platform and a second platform. The first platform supports a plurality of items to be bonded together in a first bonding process. At least one of the first platform or the second platform applies a pressing force to the plurality of items during the bonding process. The bonding apparatus includes a heater to apply thermal energy to at least one of the first platform or the second platform. Performing the first bonding process raises a platform temperature of the second platform to a temperature that could potentially damage an item, such as a semiconductor item, that undergoes a second bonding process performed using the bonding apparatus without cooling the second platform.

The bonding apparatus includes a liquid cooling module that performs a liquid cooling process to cool the second platform after the first bonding process and before a second bonding process. The liquid cooling module at least one of cools a liquid or circulates the liquid through a cooling channel. Using the liquid cooling module provides for faster and/or more efficient cooling of the second platform, in comparison with other cooling techniques such as air cooling, thereby increasing a semiconductor device production throughput associated with the bonding apparatus, such as due, at least in part, to the second bonding process being able to be performed sooner. In some embodiments, the cooling channel is arranged asymmetrically. In comparison with having the cooling channel be arranged symmetrically, the cooling channel being arranged asymmetrically increases a temperature distribution uniformity of the second platform and thus allows the second platform to be cooled more quickly, more uniformly, etc.

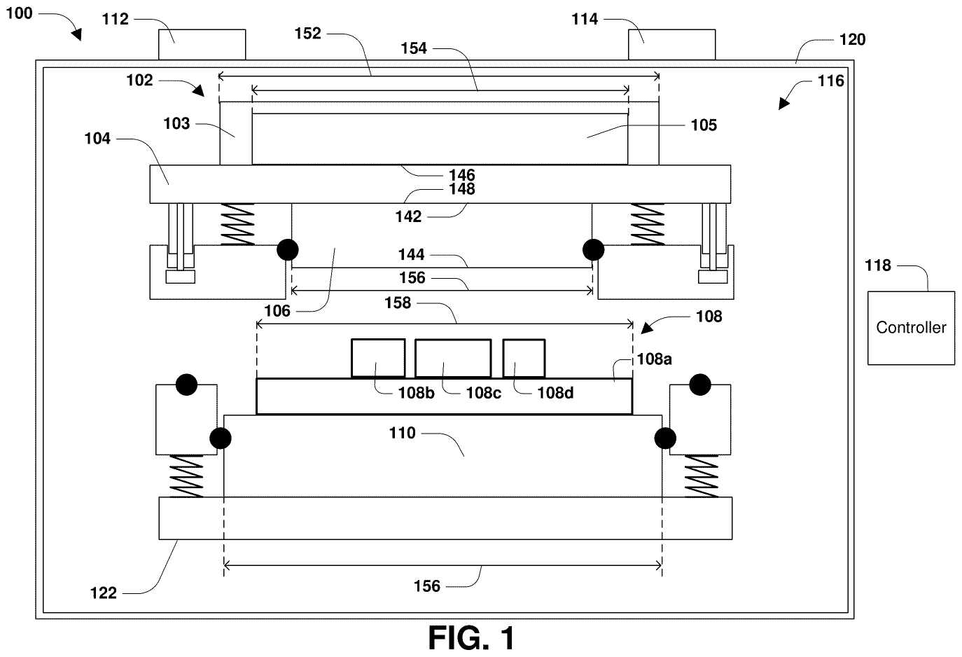

FIG. 1 illustrates a diagram depicting an apparatus 100, in accordance with some embodiments. In some embodiments, the apparatus 100 is configured to perform a first bonding process to bond a first plurality of items 108 together. In some embodiments, the apparatus 100 comprises a housing 120 defining a processing chamber 116 in which the first bonding process is performed. In some embodiments, the apparatus 100 comprises at least one of a first platform 110, a second platform 106, a liquid cooling module 102, a thermal interface layer 104, a heater 122, a controller 118, a fan unit 112, or an exhaust module 114.

In some embodiments, the apparatus 100 uses at least one of the fan unit 112 or the exhaust module 114 to control one or more environmental factors associated with the processing chamber 116, such as at least one of air purity in the processing chamber 116, one or more air flow conditions in the processing chamber 116, etc. In some embodiments, the fan unit 112 is configured to emit air (e.g., filtered air) into the processing chamber 116. In some embodiments, the fan unit 112 comprises at least one of a filter, such as at least one of a high efficiency particulate air (HEPA) filter or other suitable filter, to filter air particles from air to produce filtered air, or a fan to conduct the filtered air into the processing chamber 116. In some embodiments, the exhaust module 114 comprises at least one of an exhaust port defined in the housing 120, or a pump configured to conduct air from the processing chamber 116 to outside the processing chamber 116 through the exhaust port. In some embodiments, the controller 118 controls at least one of the exhaust module 114 or the fan unit 112 to achieve a target air purity in the processing chamber 116.

In some embodiments, the first platform 110 is configured to support the first plurality of items 108. In some embodiments, a first item 108a of the first plurality of items 108 is set upon the first platform 110. In some embodiments, the first platform 110 comprises one or more mechanical features (not shown), such as at least one of one or more grooves, one or more clamps, etc. to hold the first item 108a in a target bonding position relative to the first platform 110 during the first bonding process. FIG. 1 depicts the first item 108a in the target bonding position relative to the first platform 110, in accordance with some embodiments. In some embodiments, the first plurality of items 108 comprises a first set of items (e.g., a set of one or more items) over the first item 108a. In some embodiments, the first set of items comprises at least one of a second item 108b over the first item 108a, a third item 108c over the first item 108a, or a fourth item 108d over the first item 108a.

Although three items of the first set of items are shown in FIG. 1, any quantity of items of the first set of items are contemplated herein. In some embodiments, the first bonding process is performed to bond the first set of items to the first item 108a, such as at least one of bond the second item 108b to the first item 108a, bond the third item 108c to the first item 108a, or bond the fourth item 108d to the first item 108a.

In some embodiments, the first bonding process is a thermocompression bonding process that applies heat and pressing force to bond the first set of items to the first item 108a. In some embodiments, at least one of the first platform 110 or the second platform 106 is configured to apply a pressing force (e.g., a controlled pressing force) to the first plurality of items 108 during the first bonding process. In some embodiments, the heater 122 comprises at least one of a heating plate or other suitable heater. In some embodiments, the heater 122 is configured to apply thermal energy to the first platform 110.

In some embodiments, a first item temperature threshold associated with the first set of items is less than a second item temperature threshold associated with the first item 108a. In some embodiments, the first item temperature threshold corresponds to a first maximum temperature that an item of the first set of items can withstand during the first bonding process without at least one of causing potential damage to the item or having a potential negative impact on the first bonding process. In some embodiments, the second item temperature threshold corresponds to a second maximum temperature that the first item 108a can withstand during the first bonding process without at least one of causing potential damage to the first item 108a or having a potential negative impact on the first bonding process. In some embodiments, at least one of the heater 122 or the liquid cooling module 102 is controlled to keep a temperature associated with an item of the first set of items less than the first item temperature threshold during the first bonding process, thereby protecting the first set of items from potential damage in the first bonding process. In some embodiments, at least one of the heater 122 or the liquid cooling module 102 is controlled to keep a temperature associated with the first item 108a less than the second item temperature threshold during the first bonding process, thereby protecting the first item 108a from potential damage in the first bonding process. In some embodiments, the controller 118 is configured to control at least one of the heater 122 or the liquid cooling module 102 to regulate at least one of a first platform temperature associated with the first platform 110 or a second platform temperature associated with the second platform 106.

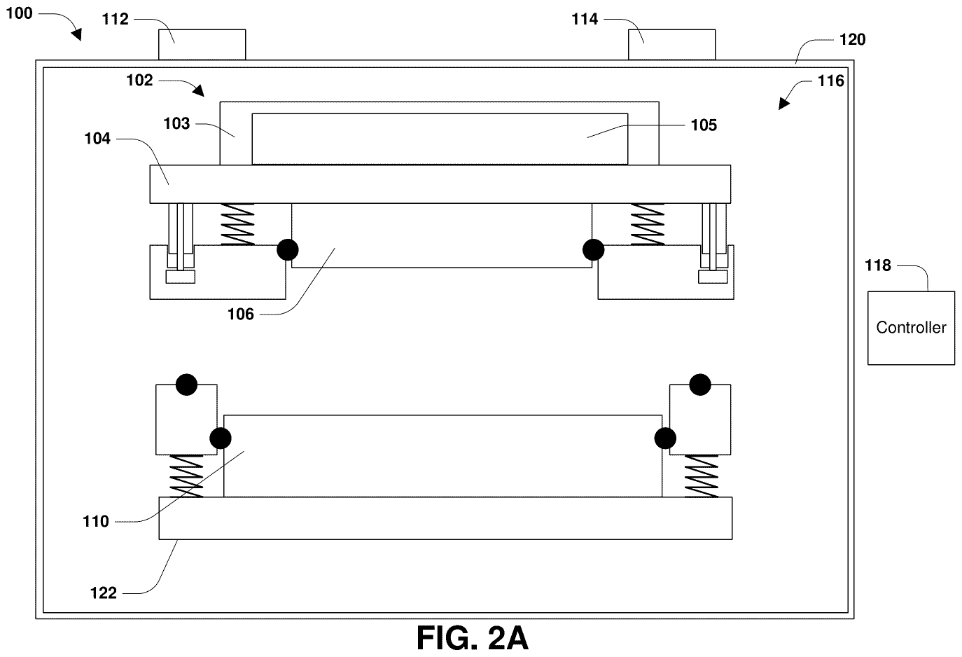

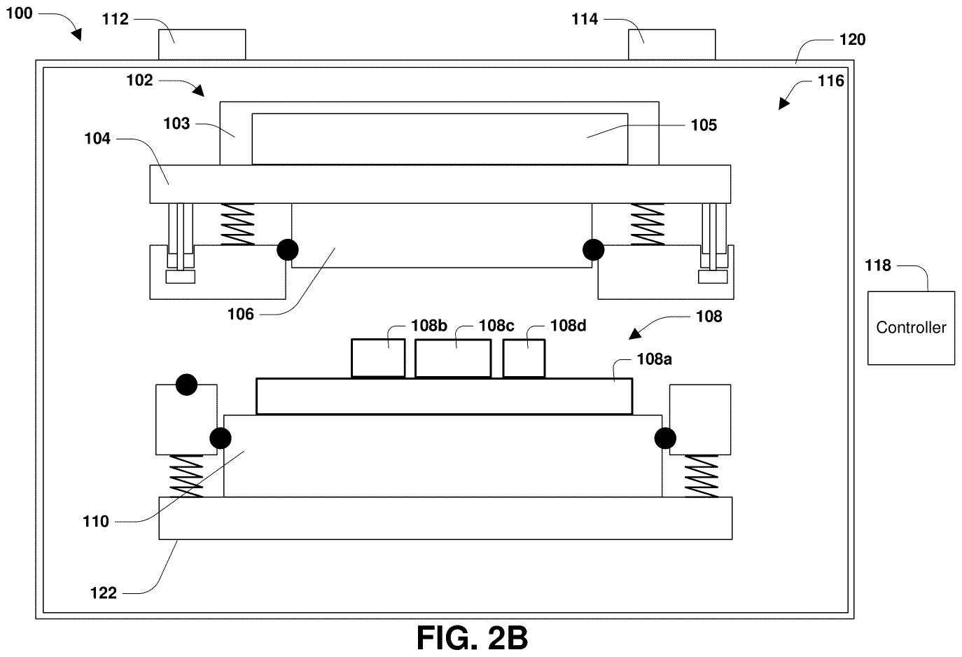

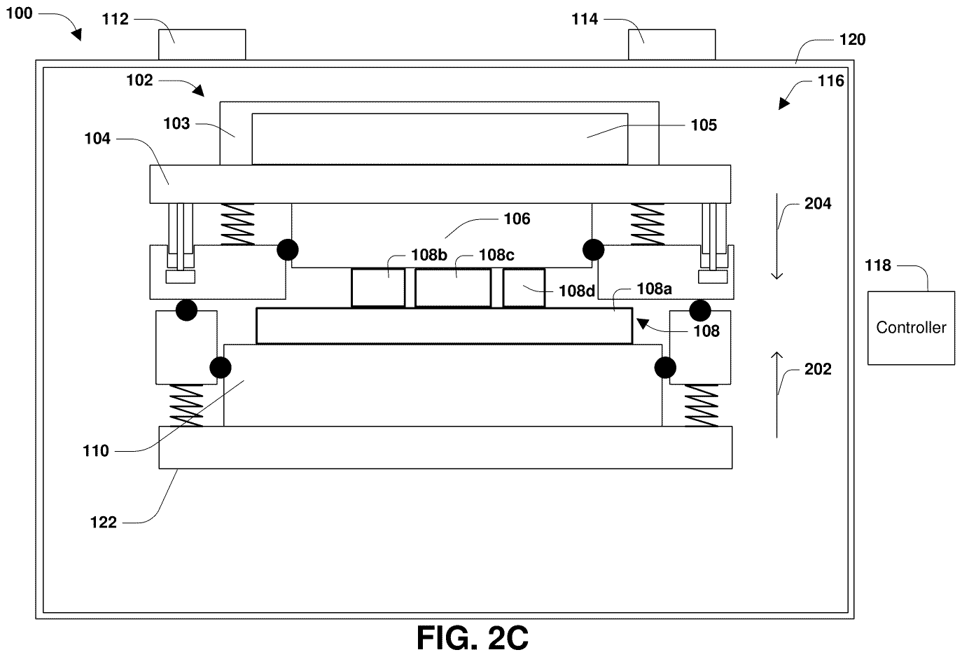

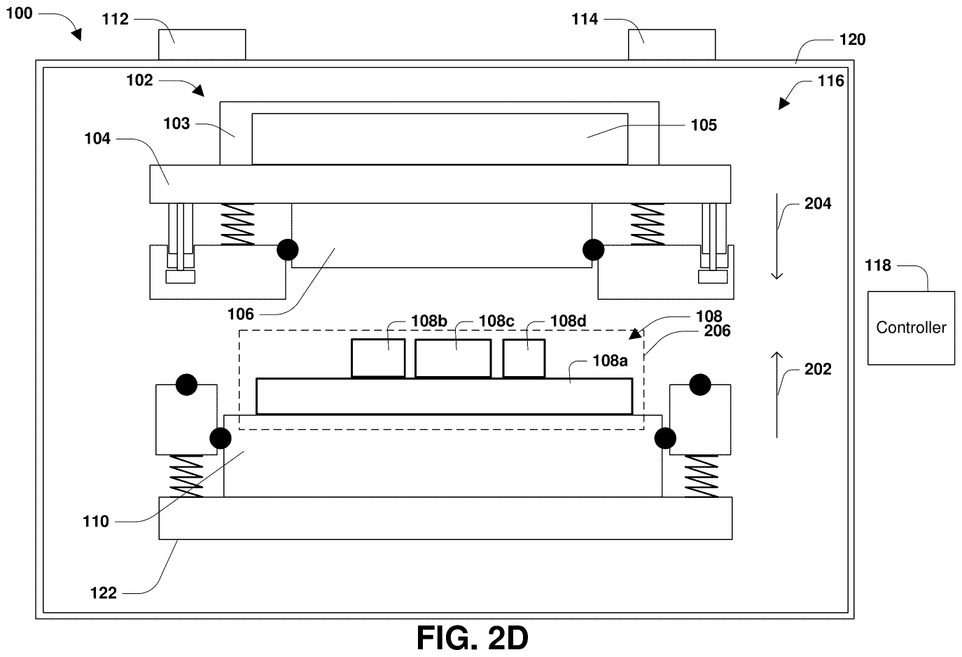

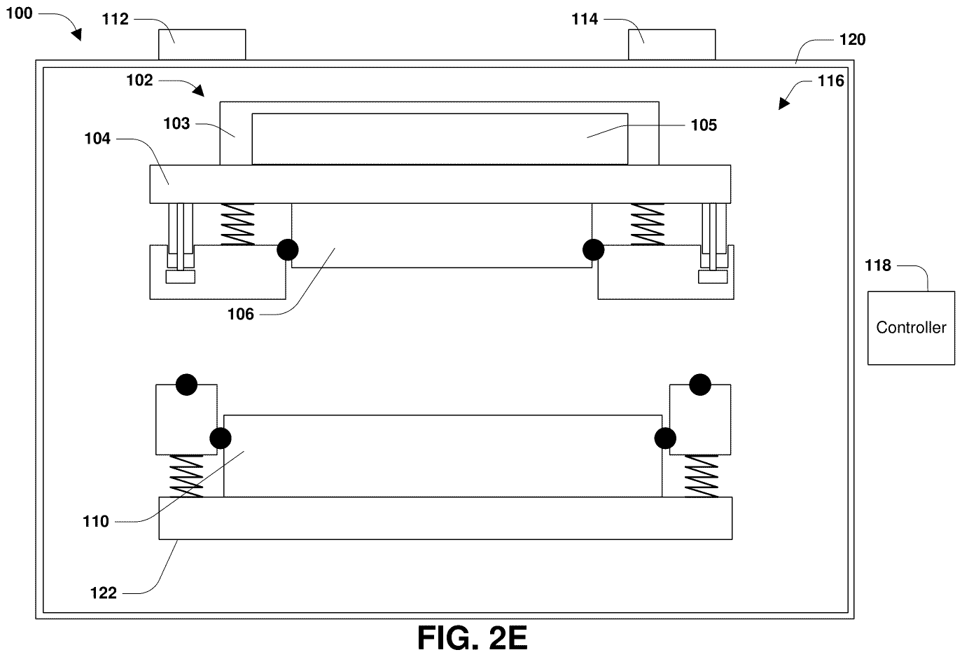

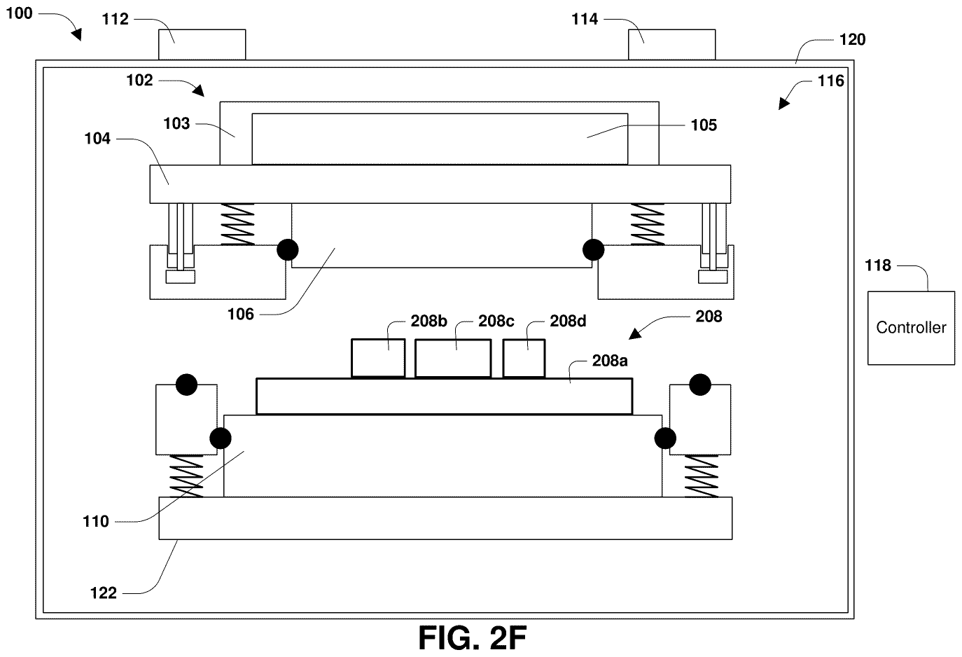

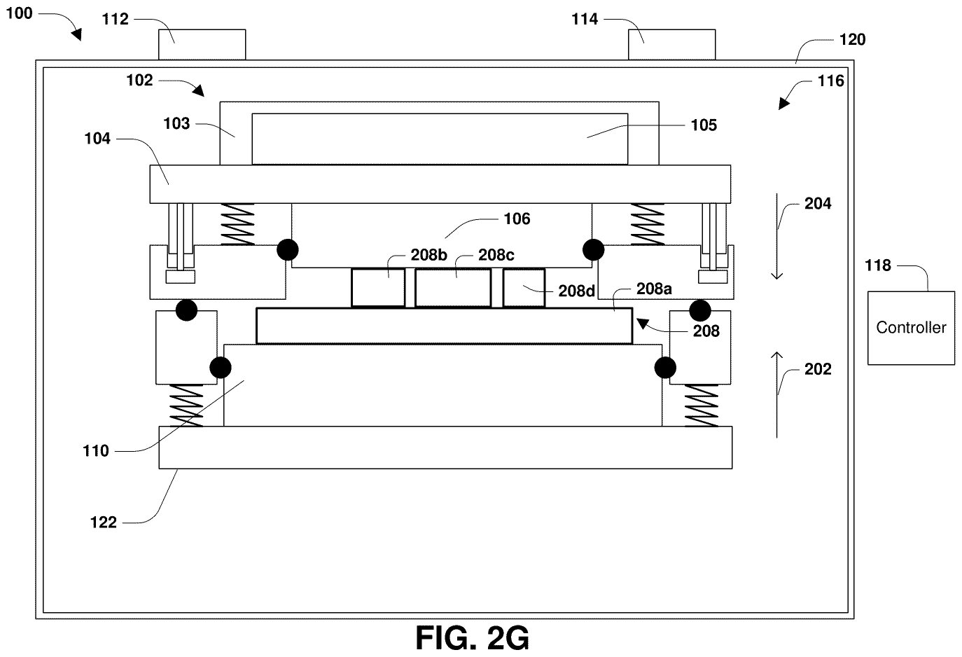

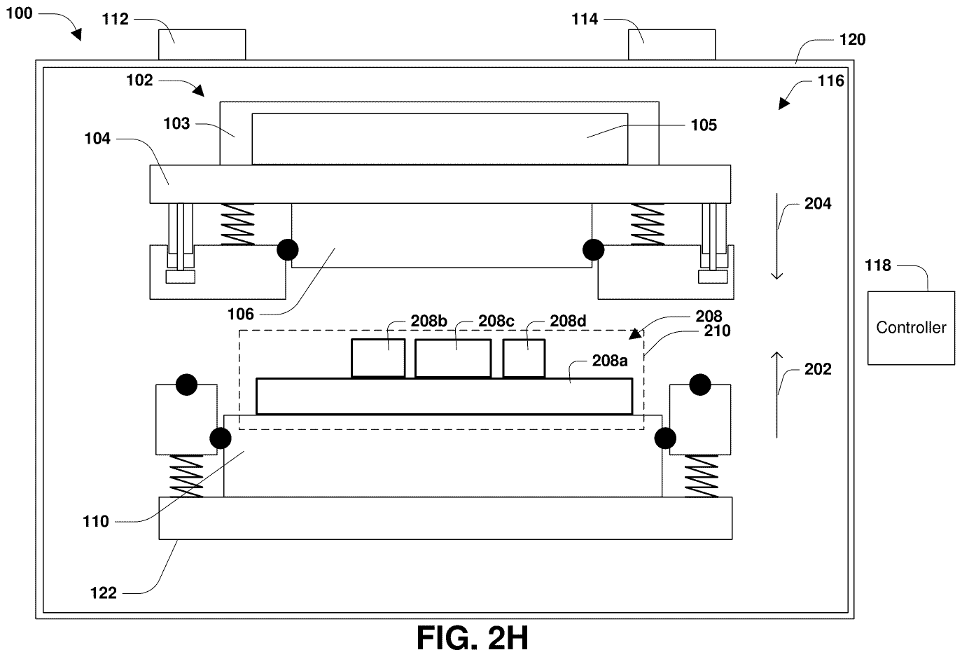

FIGS. 2A-2H illustrate a scenario in which the apparatus 100 is used to perform bonding processes including the first bonding process, in accordance with some embodiments. FIG. 2A illustrates the apparatus 100 without the first plurality of items 108 in the processing chamber 116, in accordance with some embodiments. FIGS. 2B-2D illustrate performance of the first bonding process to bond the first plurality of items 108. In some embodiments, the first plurality of items 108 is transferred from outside the processing chamber 116 into the processing chamber 116 using at least one of a robotic arm or other suitable device. FIG. 2B illustrates the apparatus 100 after the first plurality of items 108 is transferred into the processing chamber 116, in accordance with some embodiments.

In some embodiments, at least one of the controller 118 or the heater 122 is configured to control the first platform temperature associated with the first platform 110 based upon at least one of a first target platform temperature or a first range of target platform temperatures. The first range of target platform temperatures ranges from a first minimum target platform temperature to a first maximum target platform temperature. The first platform target temperature is at least one of between about 150 degrees Celsius to about 210 degrees Celsius, between about 170 degrees Celsius to about 190 degrees Celsius, between about 175 degrees Celsius to about 185 degrees Celsius, or about 180 degrees Celsius.

The first minimum target platform temperature is at least one of between about 150 degrees Celsius to about 180 degrees Celsius, between about 170 degrees Celsius to about 180 degrees Celsius, about 179 degrees Celsius, or about 180 degrees Celsius. The first maximum target platform temperature is at least one of between about 180 degrees Celsius to about 210 degrees Celsius, between about 180 degrees Celsius to about 190 degrees Celsius, about 182 degrees Celsius, or about 181 degrees Celsius. Other values of the first platform target temperature, the first minimum target platform temperature and the first maximum target platform temperature are within the scope of the present disclosure.

In some embodiments, an output heat level of the heater 122 is controlled to maintain the first platform temperature associated with the first platform 110 to be about the first platform target temperature or to be within the first range of target platform temperatures. In some embodiments, the apparatus 100 comprises a first platform feedback sensor (not shown) configured to provide temperature measurements. In some embodiments, the first platform feedback sensor is configured to provide a first measured platform temperature indicative of a measurement, by the first platform feedback sensor, of the first platform temperature associated with the first platform 110. In some embodiments, the output heat level of the heater 122 is controlled based upon the first measured platform temperature. In some embodiments, the output heat level is increased in response to determining that the first measured platform temperature is less than the first target platform temperature or less than the first minimum target platform temperature of the first range of target platform temperatures. In some embodiments, the controller 118 increases the output heat level by transmitting, over at least one of a wired connection or a wireless connection, a message to the heater 122 instructing the heater 122 to increase the output heat level. In some embodiments, the output heat level is decreased in response to determining that the first measured platform temperature is greater than the first target platform temperature or greater than the first maximum target platform temperature of the first range of target platform temperatures. In some embodiments, the controller 118 decreases the output heat level by transmitting, over at least one of a wired connection or a wireless connection, a message to the heater 122 instructing the heater 122 to decrease the output heat level. In some embodiments, during the first bonding process, first thermal energy is applied to one or more items of the first plurality of items 108 (e.g., the first thermal energy is transferred from at least one of the heater 122 or the first platform 110 to the one or more items of the first plurality of items 108). In some embodiments, the first thermal energy being applied to the one or more items of the first plurality of items 108 during the first bonding process increases a temperature of the one or more items.

In some embodiments, at least one of the first platform 110 or the second platform 106 is configured to apply a first pressing force (e.g., a controlled pressing force) to the first plurality of items 108 during the first bonding process. In some embodiments, the first pressing force is applied using at least one of a first platform driver (not shown) configured to apply a first platform driving force to the first platform 110 in a direction 202 (shown in FIG. 2C) or a second platform driver (not shown) configured to apply a second platform driving force to the second platform 106 in a direction 204 (shown in FIG. 2C). In some embodiments, the first platform driver comprises at least one of an actuator (e.g., at least one of a pneumatic actuator, a hydraulic actuator, etc.), a motor, an electromagnetic drive, etc. In some embodiments, the first platform driver applying the first platform driving force to the first platform 110 moves the first platform 110 in the direction 202. In some embodiments, the second platform driver comprises at least one of an actuator (e.g., at least one of a pneumatic actuator, a hydraulic actuator, etc.), a motor, an electromagnetic drive, etc. In some embodiments, the second platform driver applying the second platform driving force to the second platform 106 moves the second platform 106 in the direction 204.

FIG. 2C illustrates application of the first pressing force to the first plurality of items 108 during the first bonding process, in accordance with some embodiments. In some embodiments, application of the first pressing force compresses the first plurality of items 108 together. In some embodiments, at least one of applying the first pressing force to the first plurality of items 108 or applying the first thermal energy to the one or more items of the first plurality of items 108 during the first bonding process causes one, some or all items of the first set of items to be bonded to the first item 108a. In some embodiments, during the first bonding process, the apparatus 100 applies the first pressing force to the first plurality of items 108 using at least one of the first platform 110 or the second platform 106 for a first period of time. In some embodiments, a duration of the first period of time is based upon a predefined duration value stored in memory. The duration of the first period of time is at least one of between about 30 seconds to about 100 minutes, between about 3 minutes to about 10 minutes, or about 6 minutes. Other values of the duration of the first period of time are within the scope of the present disclosure.

In some embodiments, the first item 108a comprises a first set of bonding components (e.g., a first set of one or more bonding components) at least one of aligned with or configured to interface with a second set of bonding components (e.g., a second set of one or more bonding components) of the second item 108b. In some embodiments, the first bonding process joins one or more bonding components of the first set of bonding components with one or more bonding components of the second set of bonding components. In some embodiments, at least one of applying the first pressing force to the first plurality of items 108 or applying the first thermal energy to the one or more items of the first plurality of items 108 during the first bonding process causes the second item 108b to be bonded to the first item 108a, such as due, at least in part, to at least one of increasing, by way of the first thermal energy, molecular mobility of at least one of the first set of bonding components of the first item 108a or the second set of bonding components of the second item 108b, thereby improving a conformity of a bonding component of the first set of bonding components with a bonding component of the second set of bonding components, enhancing, by way of the first thermal energy, atomic diffusion of at least one of the first set of bonding components or the second set of bonding components, thereby facilitating creation of bonds (e.g., interatomic bonds) between the first set of bonding components and the second set of bonding components, triggering, by way of the first thermal energy, chemical reactions at an interface between a bonding component of the first set of bonding components and a bonding component of the second set of bonding components, thereby improving a bond strength between the bonding component of the first set of bonding components and the bonding component of the second set of bonding components, promoting, by way of the first pressing force, direct contact between a bonding component of the first set of bonding components and a bonding component of the second set of bonding components, or mitigating, by way of the first pressing force, formation of gaps (e.g., air gaps) between a bonding component of the first set of bonding components and a bonding component of the second set of bonding components.

In some embodiments, the first item 108a comprises a third set of bonding components (e.g., a third set of one or more bonding components) at least one of aligned with or configured to interface with a fourth set of bonding components (e.g., a fourth set of one or more bonding components) of the third item 108c. In some embodiments, the first bonding process joins one or more bonding components of the third set of bonding components with one or more bonding components of the fourth set of bonding components. In some embodiments, at least one of applying the first pressing force to the first plurality of items 108 or applying the first thermal energy to the one or more items of the first plurality of items 108 during the first bonding process causes the third item 108c to be bonded to the first item 108a, such as due, at least in part, to at least one of increasing, by way of the first thermal energy, molecular mobility of at least one of the third set of bonding components of the first item 108a or the fourth set of bonding components of the third item 108c, enhancing, by way of the first thermal energy, atomic diffusion of at least one of the third set of bonding components or the fourth set of bonding components, triggering, by way of the first thermal energy, chemical reactions at an interface between a bonding component of the third set of bonding components and a bonding component of the fourth set of bonding components, promoting, by way of the first pressing force, direct contact between a bonding component of the third set of bonding components and a bonding component of the fourth set of bonding components, or mitigating, by way of the first pressing force, formation of gaps (e.g., air gaps) between a bonding component of the third set of bonding components and a bonding component of the fourth set of bonding components.

In some embodiments, the first item 108a comprises a fifth set of bonding components (e.g., a fifth set of one or more bonding components) at least one of aligned with or configured to interface with a sixth set of bonding components (e.g., a sixth set of one or more bonding components) of the fourth item 108d. In some embodiments, the first bonding process joins one or more bonding components of the fifth set of bonding components with one or more bonding components of the sixth set of bonding components. In some embodiments, at least one of applying the first pressing force to the first plurality of items 108 or applying the first thermal energy to the one or more items of the first plurality of items 108 during the first bonding process causes the fourth item 108d to be bonded to the first item 108a, such as due, at least in part, to at least one of increasing, by way of the first thermal energy, molecular mobility of at least one of the fifth set of bonding components of the first item 108a or the sixth set of bonding components of the fourth item 108d, enhancing, by way of the first thermal energy, atomic diffusion of at least one of the fifth set of bonding components or the sixth set of bonding components, triggering, by way of the first thermal energy, chemical reactions at an interface between a bonding component of the fifth set of bonding components and a bonding component of the sixth set of bonding components, promoting, by way of the first pressing force, direct contact between a bonding component of the fifth set of bonding components and a bonding component of the sixth set of bonding components, or mitigating, by way of the first pressing force, formation of gaps (e.g., air gaps) between a bonding component of the fifth set of bonding components and a bonding component of the sixth set of bonding components.

In some embodiments, in response to applying the first pressing force to the first plurality of items 108 for the first period of time, the apparatus 100 performs a first platform separation process. In some embodiments, the first platform separation process comprises at least one of moving the first platform 110 in a direction (e.g., the direction 204) away from the first plurality of items 108 using the first platform driver, or moving the second platform 106 in a direction (e.g., the direction 202) away from the first plurality of items 108 using the second platform driver. FIG. 2D illustrates the apparatus 100 after the first platform separation process is performed, in accordance with some embodiments.

In some embodiments, the first bonding process produces a first joined semiconductor item 206 comprising the first plurality of items 108 where one, some, or all of the first set of items are bonded to the first item 108a. In some embodiments, in response to completing the first platform separation process, the first joined semiconductor item 206 is transferred from the processing chamber 116 to outside the processing chamber 116 using at least one of a robotic arm or other suitable device. In some embodiments, the first bonding process is considered to be complete in response to performing the first platform separation process. FIG. 2E illustrates the apparatus 100 after the first joined semiconductor item 206 is transferred to outside the processing chamber 116, in accordance with some embodiments.

In some embodiments, the first bonding process causes the second platform temperature associated with the second platform 106 to increase from a first temperature (e.g., 50 degrees Celsius) at a beginning of the first bonding process to a second temperature (e.g., 57 degrees Celsius) at an end of the first bonding process, such as due, at least in part, to heat transfer from at least one of the heater 122, the first platform 110, or the first plurality of items 108 to the second platform 106 during the first bonding process. In some embodiments, if a subsequent bonding process were to be started while the second platform temperature associated with the second platform 106 is the second temperature, an item associated with the subsequent bonding process (e.g., at least one of items 208b, 208c, or 208d) could potentially be damaged due to a temperature associated with the item reaching and/or exceeding an item threshold associated with the item.

In some embodiments, the liquid cooling module 102 is configured to perform a first cooling process to cool one or more components of the apparatus 100, such as the second platform 106. In some embodiments, the first cooling process is initiated in response to at least one of completing the first bonding process to produce the first joined semiconductor item 206, performing the first platform separation process, transferring the first joined semiconductor item 206 from the processing chamber 116 to outside the processing chamber 116, determining that the second platform temperature associated with the second platform 106 meets one or more conditions associated with triggering the first cooling process, etc. In some embodiments, the first cooling process is performed after the first bonding process is completed. Embodiments are contemplated in which the first cooling process is initiated before the first bonding process is completed.

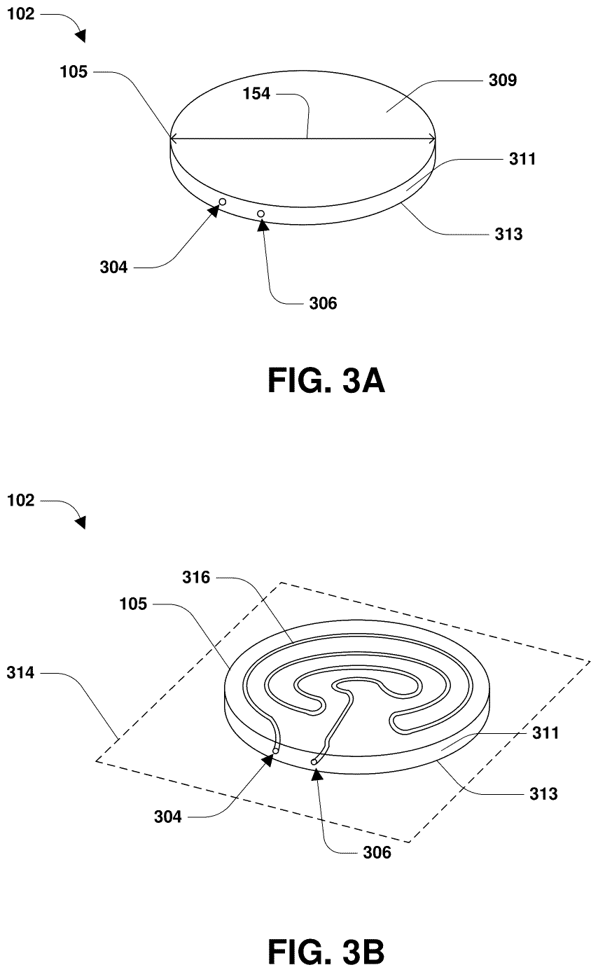

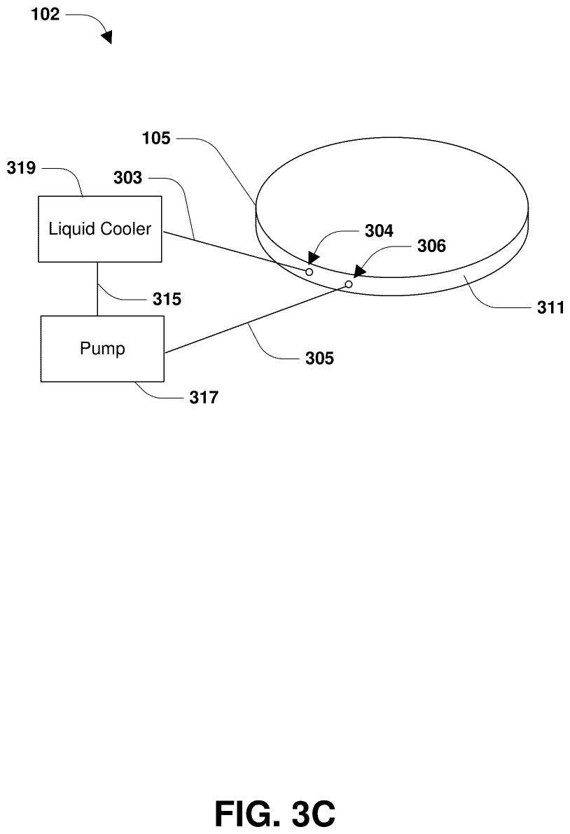

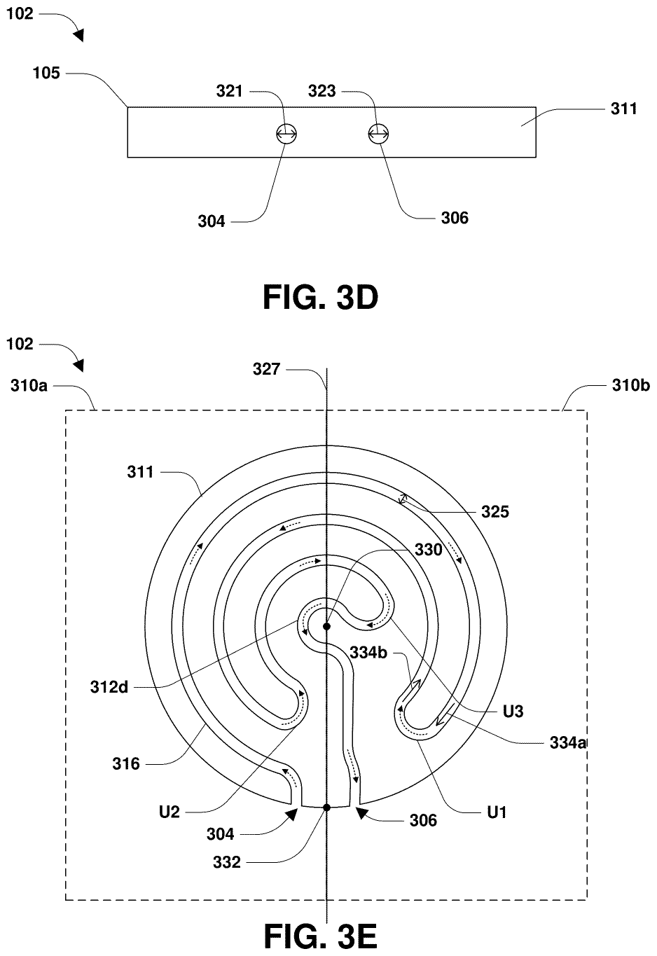

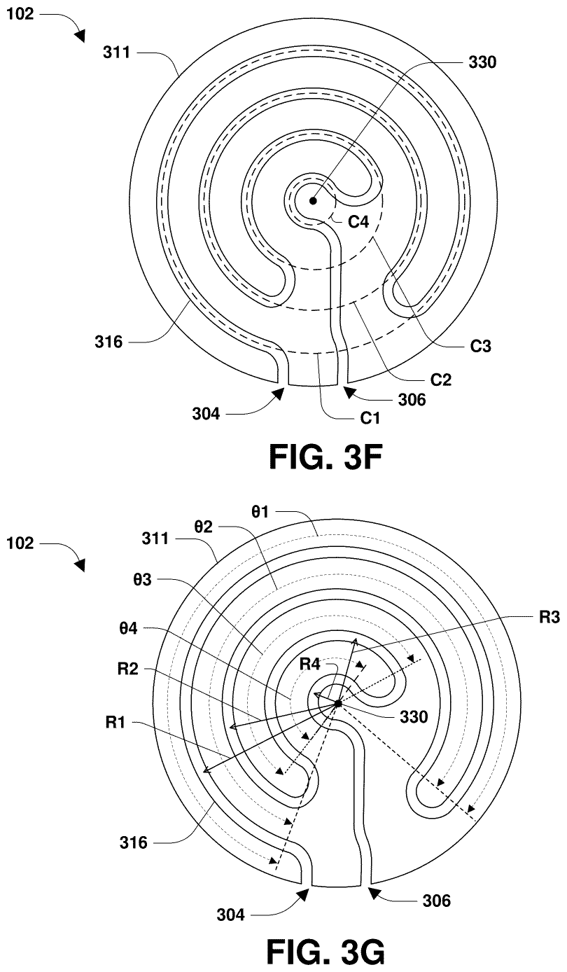

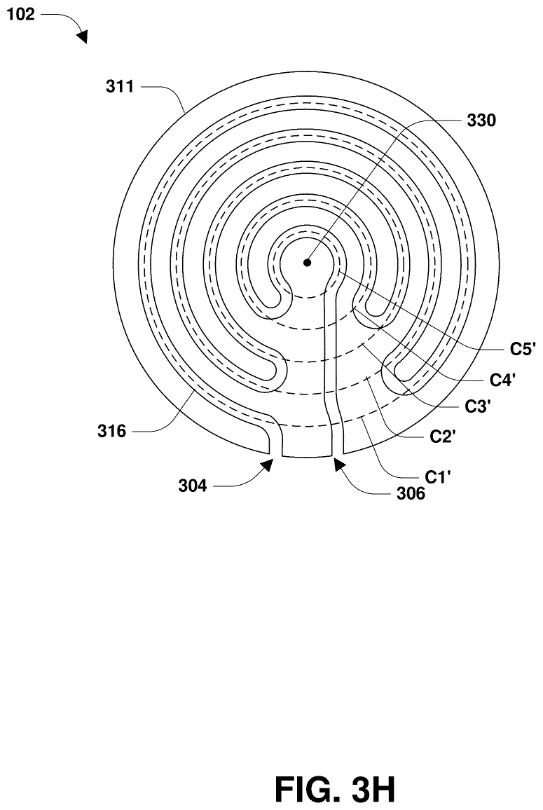

In some embodiments, the first cooling process comprises conducting a liquid through a cooling channel. In some embodiments, the liquid comprises at least one of water or one or more other liquids. In some embodiments, the liquid comprises one or more additives to at least one of decrease a freezing point associated with the liquid, increase a boiling point associated with the liquid. In some embodiments, the liquid is cooled by a liquid cooler 319 (shown in FIG. 3C) comprising at least one of a heat exchanger, a radiator, a cooling tower, or other suitable cooling device. In some embodiments, the first cooling process decreases the second platform temperature associated with the second platform 106 via at least one of heat being transferred from the second platform 106 to the liquid flowing through the cooling channel due to a temperature difference between the liquid and the second platform 106, or the liquid carrying away the heat by way of the (heated) liquid flowing along the cooling channel, wherein, in accordance with some embodiments, the liquid is thereafter cooled by the liquid cooler 319 and cycled back into the cooling channel. In some embodiments, the liquid cooling module 102 comprises at least one of a module housing 103 in which one or more components of the liquid cooling module 102 are located or a cooling channel housing 105 through which at least a portion of the cooling channel extends. In some embodiments, the cooling channel housing 105 is in a space defined by the module housing 103.

In some embodiments, a size 152 (shown in FIG. 1) of the module housing 103 is greater than a size 154 (shown in FIG. 1 and FIG. 3A) of the cooling channel housing 105. In some embodiments, the size 154 corresponds to a diameter of the cooling channel housing 105. The size 152 of the module housing 103 is at least one of between about 100 millimeters to about 1,000 millimeters, between about 300 millimeters to about 500 millimeters, or about 400 millimeters. The size 154 of the cooling channel housing 105 is at least one of between about 50 millimeters to about 800 millimeters, between about 100 millimeters to about 500 millimeters, between about 100 millimeters to about 300 millimeters, or about 200 millimeters. Other values of the size 152 of the module housing 103 and the size 154 of the cooling channel housing 105 are within the scope of the present disclosure. In some embodiments, a first platform size 156 (e.g., a platform diameter) of the first platform 110 is greater than a second platform size 157 (e.g., a platform diameter) of the second platform 106. In some embodiments, an item size 158 (e.g., a wafer diameter) of the first item 108a is greater than the second platform size 157 of the second platform 106. In some embodiments, the first platform size 156 of the first platform 110 is greater than the item size 158 (e.g., a wafer diameter) of the first item 108a.

In some embodiments, the heat is transferred from the second platform 106 to the liquid through one or more intermediary layers, such as at least one of the thermal interface layer 104, a wall of a conduit that defines the cooling channel through which the liquid flows, etc. In some embodiments, the thermal interface layer 104 comprises one or more materials with a thermal conductivity that is greater than a thermal conductivity threshold. The thermal conductivity threshold is between about 1 watt per meter per kelvin to about 15 watts per meter per kelvin. Other values of the thermal conductivity threshold are within the scope of the present disclosure. In some embodiments, the thermal interface layer 104 comprises at least one of a metal, a phase change material, a thermal paste, a thermal pad, or a graphite sheet. In some embodiments, the thermal interface layer 104 at least one of accelerates or aids cooling of the second platform 106, such as due, at least in part, to at least one of the thermal interface layer 104 decreasing thermal resistance between the second platform 106 and the liquid, the thermal interface layer 104 enhancing heat transfer efficiency from the second platform 106 to the liquid, or the thermal interface layer 104 filling gaps (e.g., air gaps) and/or irregularities between the second platform 106 and at least one of the liquid cooling module 102 or the conduit defining the cooling channel.

FIGS. 3A-3H illustrate views of the liquid cooling module 102, in accordance with some embodiments. FIG. 3A illustrates a perspective view of the liquid cooling module 102, in accordance with some embodiments. In some embodiments, the cooling channel housing 105 comprises at least one of a first surface 309 (e.g., a top surface), a second surface 313 (e.g., a bottom surface), or a peripheral wall 311 extending from the first surface 309 to the second surface 313. In some embodiments, at least a portion of the cooling channel is in the cooling channel housing 105. In some embodiments, the peripheral wall 311 is cylindrical.

FIG. 3B illustrates a perspective view of the liquid cooling module 102 without the first surface 309 (e.g., the top surface) to show a conduit 316 defining the cooling channel, in accordance with some embodiments. In some embodiments, the cooling channel is arranged asymmetrically along a plane 314. Embodiments are contemplated in which the cooling channel is arranged symmetrically along the plane 314. In some embodiments, the plane 314 is at least one of parallel or about parallel to a surface of the second platform 106, such as at least one of a top surface 142 (shown in FIG. 1) of the second platform 106 or a bottom surface 144 of the second platform 106, or parallel or about parallel to a surface of the thermal interface layer 104, such as at least one of a top surface 146 (shown in FIG. 1) of the thermal interface layer 104 or a bottom surface 144 of the thermal interface layer 104.

In some embodiments, the cooling channel housing 105 defines at least one of an inlet 304 or an outlet 306. In some embodiments, the inlet 304 at least one of comprises or is aligned with a first end of the conduit 316. In some embodiments, the outlet 306 at least one of comprises or is aligned with a second end of the conduit 316. In some embodiments, cooled liquid provided by the liquid cooler 319 enters the inlet 304, and as the cooled liquid is conducted through the cooling channel defined by the conduit 316 after entering the inlet 304, the cooled liquid absorbs heat from the second platform 106 to produce heated liquid. In some embodiments, the heated liquid exits the outlet 306 and is thereafter cooled by the liquid cooler 319 and cycled back into the cooling channel defined by the conduit 316 through the inlet 304. In some embodiments, the liquid cooling module 102 comprises a pump 317 (shown in FIG. 3C) configured to circulate the liquid through at least one of the cooling channel or the liquid cooler 319.

In some embodiments, at least one of the inlet 304 or the outlet 306 is coupled to at least one of the liquid cooler 319 or the pump 317 via one or more conduits. FIG. 3C illustrates connections between the liquid cooler 319, the pump 317, the inlet 304, or the outlet 306, in accordance with some embodiments. In some embodiments, the liquid cooler 319 is coupled to the inlet 304 via one or more conduits 303. In some embodiments, the pump 317 is coupled to the liquid cooler 319 via one or more conduits 315. In some embodiments, the pump 317 is coupled to the outlet 306 via one or more conduits 305. Other connection schemes associated with the liquid cooling module 102 other than those shown in FIG. 3C are within the scope of the present disclosure.

FIG. 3D illustrates a view of a portion of the peripheral wall 311 of the cooling channel housing 105 defining the inlet 304 and the outlet 306, in accordance with some embodiments. A diameter 321 of the inlet 304 is at least one of between about 1 millimeter to about 100 millimeters, or between about 5 millimeters to about 15 millimeters. A diameter 323 of the outlet 306 is at least one of between about 1 millimeter to about 100 millimeters, or between about 5 millimeters to about 15 millimeters. A diameter 325 (shown in FIG. 3E) of the cooling channel is at least one of between about 1 millimeter to about 100 millimeters, or between about 5 millimeters to about 15 millimeters. Other values of the diameter 321 of the inlet 304, the diameter 323 of the outlet 306, and the diameter 325 of the cooling channel are within the scope of the present disclosure. In some embodiments, the diameter 325 of the cooling channel corresponds to an inside diameter of the conduit 316 defining the cooling channel. In some embodiments, at least one of the diameter 321 of the inlet 304 or the diameter 323 of the outlet 306 is about equal to the diameter 325 of the cooling channel.

FIG. 3E illustrates a top view of the conduit 316 relative to the peripheral wall 311 of the cooling channel housing 105, in accordance with some embodiments. FIG. 3E provides representations of a first zone 310a, a second zone 310b, and a line 327 that separates the first zone 310a from the second zone 310b. In some embodiments, the line 327 extends through at least one of a center point 330 of at least one of the peripheral wall 311, the cooling channel housing 105, or a circle (e.g., at least one of circle C1, circle C2, etc.) associated with a channel section of the cooling channel, or a point 332 between the inlet 304 and the outlet 306 (e.g., the point 332 is equidistant or about equidistant to the inlet 304 and the outlet 306). In some embodiments, the first zone 310a comprises a first section of the plane 314 (shown in FIG. 3B) and the second zone 310b comprises a second section of the plane 314.

In some embodiments, the cooling channel comprises a set of turning regions (e.g., U-shaped turning regions), such as at least one of a turning region U1, a turning region U2, a turning region U3, a turning region U4, or one or more other turning regions. Although four turning regions of the set of turning regions are shown in FIG. 3E, any quantity of turning regions of the set of turning regions are contemplated herein. In some embodiments, along a turning region (e.g., at least one of the turning region U1, the turning region U2, the turning region U3, the turning region U4, etc.) of one, some or all of the set of turning regions, a direction along which the cooling channel conducts liquid shifts from a first direction (e.g., direction 334a) to a second direction (e.g., direction 334b), wherein an angle between the first direction and the second direction is at least one of between about 90 degrees to about 180 degrees, between about 135 degrees to about 180 degrees, between about 170 degrees to about 180 degrees, or other angle.

In some embodiments, the set of turning regions are split among the first zone 310a and the second zone 310b such that a quantity of turning regions in the first zone 310a is about equal to a quantity of turning regions in the second zone 310b. In some embodiments, with respect to an order in which liquid flows through the set of turning regions, odd turning regions (e.g., turning region U1 and turning region U3) are positioned in the second zone 310b and even turning regions (e.g., turning region U2 and turning region U4) are positioned in the first zone 310a.

In some embodiments, the cooling channel comprises a set of channel sections. In some embodiments, each channel section of one, some, or all of the set of channel sections extends along a circular arc spanning at least a portion of a circle. FIG. 3F illustrates a top view of the conduit 316 relative to the peripheral wall 311 of the cooling channel housing 105, in accordance with some embodiments in which the set of channel sections comprises 4 channel sections. In some embodiments, the set of channel sections of the cooling section comprises at least one of a first channel section extending along a first circular arc spanning a portion of a first circle C1, a second channel section extending along a second circular arc spanning a portion of a second circle C2, a third channel section extending along a third circular arc spanning a portion of a third circle C3, or a fourth channel section extending along a fourth circular arc spanning a portion of a fourth circle C4. In some embodiments, the center point 330 corresponds to a center point of at least one of the circle C1, the circle C2, the circle C3, or the circle C4.

In some embodiments, each channel section of one, some, or all of the set of channel sections is associated with a central angle θ that is at least about 180 degrees. FIG. 3G illustrates a top view of the conduit 316 relative to the peripheral wall 311 of the cooling channel housing 105 with representations of central angles associated with the set of channel sections, in accordance with some embodiments. The central angles include a central angle θ1 associated with the first channel section along a portion of the first circle C1, a central angle θ2 associated with the second channel section along a portion of the second circle C2, a central angle θ3 associated with the third channel section along a portion of the third circle C3, and a central angle θ4 associated with the fourth channel section along a portion of the fourth circle C4. In some embodiments, each channel section of one, some, or all of the set of channel sections is associated with a radius R relative to the center point 330. A radius of an outer channel section of the set of channel sections (e.g., a radius R1 of the first channel section) is at most about 200 millimeters. A radius R2 of the second channel section is at most about 160 millimeters. A radius R3 of the third channel section is at most about 120 millimeters. A radius R4 of the fourth channel section is at most about 80 millimeters. Other values of the radius of the outer channel section (e.g., the radius R1 of the first channel section), the radius R2, the radius R3, and the radius R4 are within the scope of the present disclosure.

A quantity of channel sections of the set of channel sections is between about 3 channel sections to about 6 channel sections. Other values of the quantity of channel sections are within the scope of the present disclosure. FIG. 3H illustrates a top view of the conduit 316 relative to the peripheral wall 311 of the cooling channel housing 105, in accordance with some embodiments in which the set of channel sections comprises 5 channel sections. In some embodiments, the set of channel sections of the cooling section comprises at least one of a channel section (e.g., an outer channel section) extending along a circular arc spanning a portion of a circle C1′, a channel section extending along a circular arc spanning a portion of a circle C2′, a channel section extending along a circular arc spanning a portion of a circle C3′, a channel section extending along a circular arc spanning a portion of a circle C4′, or a channel section extending along a circular arc spanning a portion of a circle C5′. In some embodiments, the center point 330 corresponds to a center point of at least one of the circle C1′, the circle C2′, the circle C3′, the circle C4′, or the circle C5′.

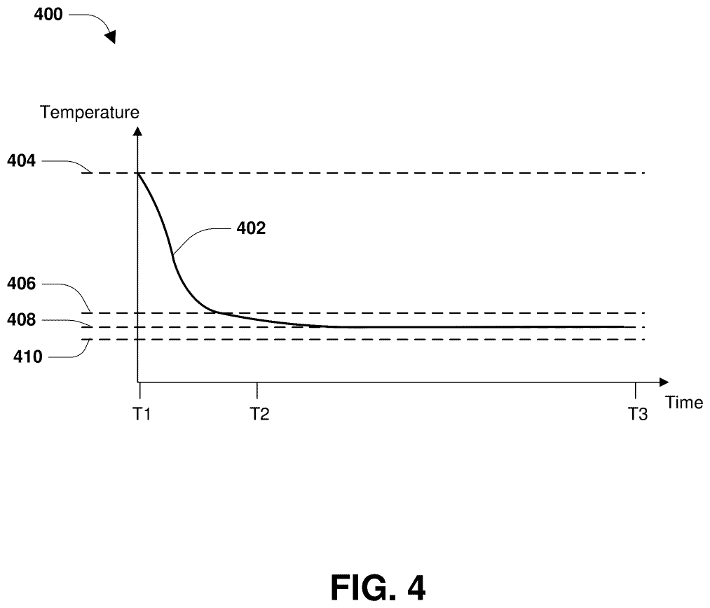

FIG. 4 illustrates a platform temperature graph 400 comprising a platform temperature curve 402 indicative of the second platform temperature associated with the second platform 106 from time T1 to time T3, in accordance with some embodiments. In some embodiments, the first cooling process is initiated at or before the time T1. In some embodiments, at the time T1, the second platform temperature begins decreasing from temperature 404 due to the first cooling process. In some embodiments, the temperature 404 corresponds to the second temperature to which the second platform temperature increases during the first bonding process. In some embodiments, in response to initiating the first cooling process, the controller 118 activates the pump 317 to circulate liquid (e.g., cooled liquid) through at least one of the liquid cooler 319 or the cooling channel (defined by the conduit 316, for example). In some embodiments, in response to initiating the first cooling process, the controller 118 activates the liquid cooler 319 to cool the liquid being circulated through at least one of the liquid cooler 319 or the cooling channel.

In some embodiments, the apparatus 100 comprises a second platform feedback sensor (not shown) configured to provide temperature measurements. In some embodiments, the second platform feedback sensor is configured to provide a second measured platform temperature indicative of a measurement, by the second platform feedback sensor, of the second platform temperature associated with the second platform 106. In some embodiments, one or more parameters such as at least one of a cooling power of the liquid cooler 319, a flow rate with which the pump 317 to circulates liquid (e.g., cooled liquid) through the cooling channel, etc. are controlled based upon the second measured platform temperature. In some embodiments, the controller 118 communicates with at least one of the liquid cooler 319 or the pump 317 over at least one of a wired connection, a wireless connection, etc.

In some embodiments, the controller 118 determines the second platform temperature associated with the second platform 106 based upon the second measured platform temperature. In some embodiments, the controller 118 receives a message indicative of the second measured platform temperature from the second platform feedback sensor via at least one of a wired connection or a wireless connection. In some embodiments, the controller 118 monitors the second platform temperature associated with the second platform 106 (by monitoring one or more updated values of the second measured platform temperature received from the second platform feedback sensor, for example). In some embodiments, in response to determining that the second platform temperature meets one or more first conditions, the controller 118 at least one of considers the first cooling process to be completed, transmits an alert indicating that the apparatus 100 is ready to perform a subsequent bonding process to a device (e.g., an item process management device configured to use the alert to at least one of schedule or trigger performance of one or more subsequent bonding processes using the apparatus 100), transmits an instruction to a semiconductor wafer handling device (e.g., at least one of a robotic arm or other suitable device) instructing the semiconductor wafer handling device to transfer a plurality of items from outside the processing chamber 116 into the processing chamber 116 (e.g., into a space between the first platform 110 and the second platform 106) to be processed in a subsequent bonding process, triggering the subsequent bonding process to be performed to bond the plurality of items together, or performs one or more other actions.

In some embodiments, in response to at least one of determining that the second platform temperature meets one or more first conditions or determining that the first cooling process is completed, the controller 118 at least one of deactivates the pump 317 or instructs the pump 317 to cease circulating liquid (or decrease a flow rate with which the liquid is circulated) through at least one of the liquid cooler 319 or the cooling channel (defined by the conduit 316, for example). In some embodiments, in response to at least one of determining that the second platform temperature meets one or more first conditions or determining that the first cooling process is completed, the controller 118 at least one of deactivates the liquid cooler 319 or instructs the liquid cooler 319 to cease cooling (or decrease cooling of) the liquid being circulated through at least one of the liquid cooler 319 or the cooling channel.

In some embodiments, the one or more first conditions comprise a first condition that the second platform temperature associated with the second platform 106 is less than a platform temperature threshold. In some embodiments, the controller 118 compares the second measured platform temperature provided by the second platform feedback sensor with the platform temperature threshold to determine whether the second platform temperature meets the first condition. In some embodiments, the platform temperature threshold corresponds to temperature 406 of FIG. 4. The platform temperature threshold is at least one of between about 30 degrees Celsius to about 70 degrees Celsius, between about 40 degrees Celsius to about 60 degrees Celsius, between about 45 degrees Celsius to about 50 degrees Celsius, about 48 degrees Celsius, or about 50 degrees Celsius. Other values of the platform temperature threshold are within the scope of the present disclosure.

In some embodiments, the one or more first conditions comprise a second condition that the second platform temperature associated with the second platform 106 is about equal to a second platform target temperature. In some embodiments, the controller 118 compares the second measured platform temperature provided by the second platform feedback sensor with the second platform target temperature to determine whether the second platform temperature meets the second condition. In some embodiments, the second platform target temperature corresponds to temperature 408 of FIG. 4. The second platform target temperature is at least one of between about 30 degrees Celsius to about 70 degrees Celsius, between about 40 degrees Celsius to about 60 degrees Celsius, between about 45 degrees Celsius to about 55 degrees Celsius, or about 50 degrees Celsius. Other values of the second platform target temperature are within the scope of the present disclosure.

In some embodiments, the one or more first conditions comprise a third condition that the second platform temperature associated with the second platform 106 is within a second range of target platform temperatures. In some embodiments, the controller 118 compares the second measured platform temperature provided by the second platform feedback sensor with the second range of target platform temperatures to determine whether the second platform temperature meets the third condition. The second range of target platform temperatures ranges from a second minimum target platform temperature to a second maximum target platform temperature. In some embodiments, at least one of the second minimum target platform temperature corresponds to the temperature 410 of FIG. 4 or the second maximum target platform temperature corresponds to the temperature 406 of FIG. 4. The second minimum target platform temperature is at least one of between about 30 degrees Celsius to about 55 degrees Celsius, between about 40 degrees Celsius to about 50 degrees Celsius, about 49 degrees Celsius, or about 50 degrees Celsius. The second maximum target platform temperature is at least one of between about 45 degrees Celsius to about 70 degrees Celsius, between about 50 degrees Celsius to about 60 degrees Celsius, about 52 degrees Celsius, or about 51 degrees Celsius. Other values of the second minimum target platform temperature and the second maximum target platform temperature are within the scope of the present disclosure.

In some embodiments, the one or more first conditions comprise a fourth condition that the second platform temperature associated with the second platform 106 has at least one of exited a transient phase or entered a steady state phase. In some embodiments, the controller 118 uses values of the second measured platform temperature provided by the second platform feedback sensor to determine a first rate at which the second platform temperature changes over time, and determines whether the second platform temperature is in the transient phase or in the steady state phase based upon the first rate. In some embodiments, the controller 118 determines that the second platform temperature associated with the second platform 106 is in the transient phase based upon the first rate being greater than a temperature change rate threshold. In some embodiments, the controller 118 determines that the second platform temperature associated with the second platform 106 is in the steady state phase based upon the first rate being less than a temperature change rate threshold. In some embodiments, the controller 118 considers the second platform temperature associated with the second platform 106 to be in the transient phase from the time T1 to time T2. In some embodiments, the controller 118 considers the second platform temperature associated with the second platform 106 to be in the steady state phase from the time T2 to time T3.

In some embodiments, a second bonding process to bond a second plurality of items 208 (shown in FIG. 2F) together is performed using the apparatus 100. In some embodiments, the second bonding process is performed in response to determining that the second platform temperature associated with the second platform 106 meets the one or more first conditions. In some embodiments, in response to determining that the second platform temperature associated with the second platform 106 meets the one or more first conditions, the item process management device transmits an instruction to the semiconductor wafer handling device instructing the semiconductor wafer handling device to transfer the second plurality of items from outside the processing chamber 116 into the processing chamber 116 (e.g., into a space between the first platform 110 and the second platform 106) to be processed in the second bonding process.

FIG. 2F illustrates the apparatus 100 after the second plurality of items 208 is transferred into the processing chamber 116, in accordance with some embodiments. In some embodiments, the first platform 110 is configured to support the second plurality of items 208. In some embodiments, a fifth item 208a of the second plurality of items 208 is set upon the first platform 110. In some embodiments, the second plurality of items 208 comprises a second set of items (e.g., a set of one or more items) over the fifth item 208a. In some embodiments, the second set of items comprises at least one of a sixth item 208b over the fifth item 208a, a seventh item 208c over the fifth item 208a, or an eighth item 208d over the fifth item 208a. Although three items of the second set of items are shown in FIG. 2F, any quantity of items of the second set of items are contemplated herein. In some embodiments, the second bonding process is performed to bond the second set of items to the fifth item 208a, such as at least one of bond the sixth item 208b to the fifth item 208a, bond the seventh item 208c to the fifth item 208a, or bond the eighth item 208d to the fifth item 208a.

In some embodiments, the second bonding process is a thermocompression bonding process that applies heat and pressing force to bond the second set of items to the fifth item 208a. In some embodiments, a third item temperature threshold associated with the second set of items is less than a fourth item temperature threshold associated with the fifth item 208a. In some embodiments, the third item temperature threshold corresponds to a third maximum temperature that an item of the second set of items can withstand during the second bonding process without at least one of causing potential damage to the item or having a potential negative impact on the second bonding process. In some embodiments, the fourth item temperature threshold corresponds to a fourth maximum temperature that the fifth item 208a can withstand during the second bonding process without at least one of causing potential damage to the fifth item 208a or having a potential negative impact on the second bonding process. In some embodiments, at least one of the heater 122 or the liquid cooling module 102 is controlled to keep a temperature associated with an item of the second set of items less than the third item temperature threshold during the second bonding process, thereby protecting the second set of items from potential damage in the second bonding process.

In some embodiments, during the second bonding process, second thermal energy is applied to one or more items of the second plurality of items 208 (e.g., the second thermal energy is transferred from at least one of the heater 122 or the first platform 110 to the one or more items of the second plurality of items 208). In some embodiments, the second thermal energy being applied to the one or more items of the second plurality of items 208 during the second bonding process increases a temperature of the one or more items.

In some embodiments, at least one of the first platform 110 or the second platform 106 is configured to apply a second pressing force (e.g., a controlled pressing force) to the second plurality of items 208 during the second bonding process. In some embodiments, the second pressing force is applied using at least one of the first platform driver configured to apply the first platform driving force to the first platform 110, or the second platform driver configured to apply the second platform driving force to the second platform 106.

FIG. 2G illustrates application of the second pressing force to the second plurality of items 208 during the second bonding process, in accordance with some embodiments. In some embodiments, application of the second pressing force compresses the second plurality of items 208 together. In some embodiments, at least one of applying the second pressing force to the second plurality of items 208 or applying the second thermal energy to the one or more items of the second plurality of items 208 during the second bonding process causes one, some or all items of the second set of items to be bonded to the fifth item 208a. In some embodiments, during the second bonding process, the apparatus 100 applies the second pressing force to the second plurality of items 208 using at least one of the first platform 110 or the second platform 106 for a second period of time. In some embodiments, a duration of the second period of time is based upon a predefined duration value stored in memory. The duration of the second period of time is at least one of between about 30 seconds to about 100 minutes, between about 3 minutes to about 10 minutes, or about 6 minutes. Other values of the duration of the second period of time are within the scope of the present disclosure.

In some embodiments, the fifth item 208a comprises a seventh set of bonding components (e.g., a seventh set of one or more bonding components) at least one of aligned with or configured to interface with an eighth set of bonding components (e.g., an eighth set of one or more bonding components) of the sixth item 208b. In some embodiments, the second bonding process joins one or more bonding components of the seventh set of bonding components with one or more bonding components of the eighth set of bonding components. In some embodiments, at least one of applying the second pressing force to the second plurality of items 208 or applying the second thermal energy to the one or more items of the second plurality of items 208 during the second bonding process causes the sixth item 208b to be bonded to the fifth item 208a, such as due, at least in part, to at least one of increasing, by way of the second thermal energy, molecular mobility of at least one of the seventh set of bonding components of the fifth item 208a or the eighth set of bonding components of the sixth item 208b, enhancing, by way of the second thermal energy, atomic diffusion of at least one of the seventh set of bonding components or the eighth set of bonding components, triggering, by way of the second thermal energy, chemical reactions at an interface between a bonding component of the seventh set of bonding components and a bonding component of the eighth set of bonding components, promoting, by way of the second pressing force, direct contact between a bonding component of the seventh set of bonding components and a bonding component of the eighth set of bonding components, or mitigating, by way of the second pressing force, formation of gaps (e.g., air gaps) between a bonding component of the seventh set of bonding components and a bonding component of the eighth set of bonding components.

In some embodiments, the fifth item 208a comprises a ninth set of bonding components (e.g., a ninth set of one or more bonding components) at least one of aligned with or configured to interface with a tenth set of bonding components (e.g., a tenth set of one or more bonding components) of the seventh item 208c. In some embodiments, the second bonding process joins one or more bonding components of the ninth set of bonding components with one or more bonding components of the tenth set of bonding components. In some embodiments, at least one of applying the second pressing force to the second plurality of items 208 or applying the second thermal energy to the one or more items of the second plurality of items 208 during the second bonding process causes the seventh item 208c to be bonded to the fifth item 208a, such as due, at least in part, to at least one of increasing, by way of the second thermal energy, molecular mobility of at least one of the ninth set of bonding components of the fifth item 208a or the tenth set of bonding components of the seventh item 208c, enhancing, by way of the second thermal energy, atomic diffusion of at least one of the ninth set of bonding components or the tenth set of bonding components, triggering, by way of the second thermal energy, chemical reactions at an interface between a bonding component of the ninth set of bonding components and a bonding component of the tenth set of bonding components, promoting, by way of the second pressing force, direct contact between a bonding component of the ninth set of bonding components and a bonding component of the tenth set of bonding components, or mitigating, by way of the second pressing force, formation of gaps (e.g., air gaps) between a bonding component of the ninth set of bonding components and a bonding component of the tenth set of bonding components.

In some embodiments, the fifth item 208a comprises an eleventh set of bonding components (e.g., an eleventh set of one or more bonding components) at least one of aligned with or configured to interface with a twelfth set of bonding components (e.g., a twelfth set of one or more bonding components) of the eighth item 208d. In some embodiments, the second bonding process joins one or more bonding components of the eleventh set of bonding components with one or more bonding components of the twelfth set of bonding components. In some embodiments, at least one of applying the second pressing force to the second plurality of items 208 or applying the second thermal energy to the one or more items of the second plurality of items 208 during the second bonding process causes the eighth item 208d to be bonded to the fifth item 208a, such as due, at least in part, to at least one of increasing, by way of the second thermal energy, molecular mobility of at least one of the eleventh set of bonding components of the fifth item 208a or the twelfth set of bonding components of the eighth item 208d, enhancing, by way of the second thermal energy, atomic diffusion of at least one of the eleventh set of bonding components or the twelfth set of bonding components, triggering, by way of the second thermal energy, chemical reactions at an interface between a bonding component of the eleventh set of bonding components and a bonding component of the twelfth set of bonding components, promoting, by way of the second pressing force, direct contact between a bonding component of the eleventh set of bonding components and a bonding component of the twelfth set of bonding components, or mitigating, by way of the second pressing force, formation of gaps (e.g., air gaps) between a bonding component of the eleventh set of bonding components and a bonding component of the twelfth set of bonding components.

In some embodiments, in response to applying the second pressing force to the second plurality of items 208 for the second period of time, the apparatus 100 performs a second platform separation process. In some embodiments, the second platform separation process comprises at least one of moving the first platform 110 in a direction (e.g., the direction 204) away from the second plurality of items 208 using the first platform driver, or moving the second platform 106 in a direction (e.g., the direction 202) away from the second plurality of items 208 using the second platform driver. FIG. 2H illustrates the apparatus 100 after the second platform separation process is performed, in accordance with some embodiments.

In some embodiments, the second bonding process produces a second joined semiconductor item 210 comprising the second plurality of items 208 where one, some, or all of the second set of items are bonded to the fifth item 208a. In some embodiments, in response to completing the second platform separation process, the second joined semiconductor item 210 is transferred from the processing chamber 116 to outside the processing chamber 116 using at least one of a robotic arm or other suitable device. In some embodiments, the second bonding process is considered to be complete in response to performing the second platform separation process.

In some embodiments, the second bonding process causes the second platform temperature associated with the second platform 106 to increase from a third temperature (e.g., 50 degrees Celsius) at a beginning of the second bonding process to a fourth temperature (e.g., 57 degrees Celsius) at an end of the second bonding process, such as due, at least in part, to heat transfer from at least one of the heater 122, the first platform 110, or the second plurality of items 208 to the second platform 106 during the second bonding process. In some embodiments, if a subsequent bonding process were to be started while the second platform temperature associated with the second platform 106 is the second temperature, an item associated with the subsequent bonding process could potentially be damaged due to a temperature associated with the item reaching and/or exceeding an item threshold associated with the item.

In some embodiments, the liquid cooling module 102 is configured to perform a second cooling process to cool one or more components of the apparatus 100, such as the second platform 106. In some embodiments, the second cooling process is initiated in response to at least one of completing the second bonding process to produce the second joined semiconductor item 210, performing the second platform separation process, transferring the second joined semiconductor item 210 from the processing chamber 116 to outside the processing chamber 116, determining that the second platform temperature associated with the second platform 106 meets one or more conditions associated with triggering the second cooling process, etc. In some embodiments, the second cooling process is performed after the second bonding process is completed. Embodiments are contemplated in which the second cooling process is initiated before the second bonding process is completed.

In some embodiments, the second cooling process comprises conducting a liquid through the cooling channel. In some embodiments, the second cooling process is performed using one or more of the techniques provided herein with respect to performing the first cooling process. In some embodiments, a third bonding process to bond a third plurality of items (not shown) together is performed using the apparatus 100. In some embodiments, the third bonding process is performed in response to at least one of completing the second cooling process or determining that the second platform temperature associated with the second platform 106 meets the one or more first conditions. In some embodiments, in response to determining that the second platform temperature associated with the second platform 106 meets the one or more first conditions, the item process management device transmits an instruction to the semiconductor wafer handling device instructing the semiconductor wafer handling device to transfer the third plurality of items from outside the processing chamber 116 into the processing chamber 116 (e.g., into a space between the first platform 110 and the second platform 106) to be processed in the third bonding process.

In some embodiments, using the liquid cooling module 102 provides for faster and/or more efficient cooling of one or more components of the apparatus 100, such as the second platform 106, in comparison with other cooling techniques such as air cooling. In some embodiments, using the liquid cooling module 102 to cool the second platform 106 results in the first cooling process being performed about 10 times faster than using other cooling techniques such as air cooling to cool the cooling second platform 106 (e.g., the liquid cooling module 102 is able to decrease the second platform temperature begins from the temperature 404 to a temperature that meets the one or more second conditions about 10 times faster), thereby increasing a semiconductor device production throughput associated with the apparatus 100, such as due, at least in part, to the second bonding process being able to be performed sooner.

In some embodiments, configuring the cooling channel to be arranged asymmetrically across the line 327 and/or to have one or more of the characteristics, features, shapes and/or configurations provided herein with respect to the cooling channel and/or the conduit 316 defining the cooling channel provides for increased temperature distribution uniformity across the second platform 106 during at least one of the transient phase or the steady state phase, faster and/or more efficient cooling of the second platform 106, a decreased duration of time in which the second platform temperature is in the transient phase, an increased duration of time in which the second platform temperature is in the steady state phase, improved temperature stability of the second platform 106, etc. In comparison with having the cooling channel be arranged symmetrically across the line 327, the cooling channel being arranged asymmetrically across the line 327 in accordance with some embodiments herein decreases a standard deviation associated with the temperature distribution uniformity from about 9% to about 6%.

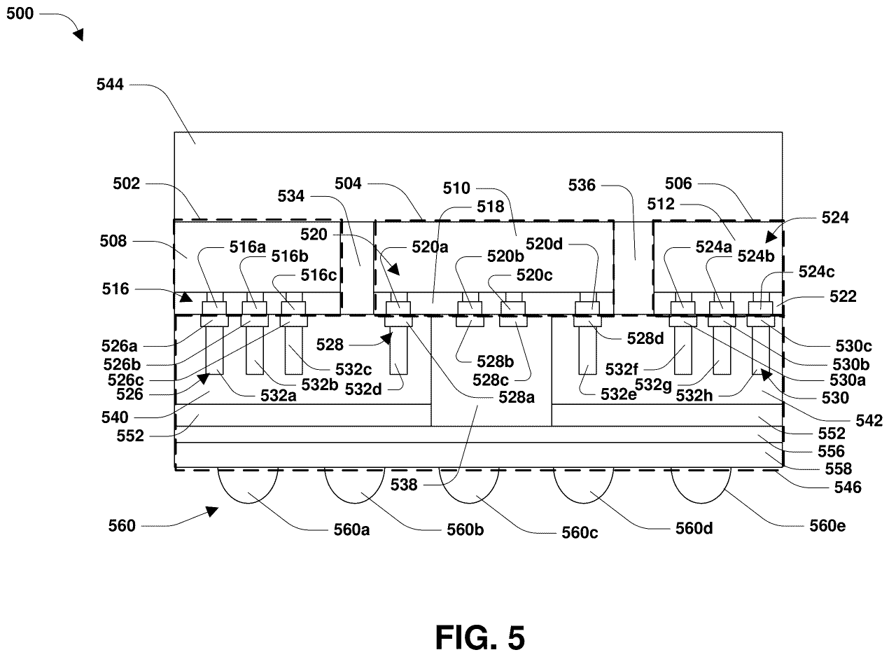

FIG. 5 illustrates a semiconductor device 500, in accordance with some embodiments. In some embodiments, the semiconductor device 500 comprises at least one of a semiconductor wafer 546, a first die 508 over the semiconductor wafer 546, a second die 510 over the semiconductor wafer 546, a third die 512 over the semiconductor wafer 546, or a fourth die 544 over at least one of the first die 508, the second die 510, or the third die 512. In some embodiments, the semiconductor device 500 has a chip-on-wafer (CoW) arrangement. In some embodiments, the semiconductor device 500 has a System on Integrated Chip (SoIC) arrangement (that is formed via at least one of hybrid bonding or fusion bonding, for example). In some embodiments, the semiconductor device 500 comprises at least one of a first oxide structure 534 between the first die 508 and the second die 510 or a second oxide structure 534 between the second die 510 and the third die 512. In some embodiments, the first oxide structure 534 comprises at least one of silicon dioxide or other suitable material. In some embodiments, the second oxide structure 536 comprises at least one of silicon dioxide or other suitable material. In some embodiments, the semiconductor wafer 546 comprises at least one of a first interposer 540 (e.g., silicon interposer), a second interposer 542 (e.g., silicon interposer), a third oxide structure 538 between the first interposer 540 and the second interposer 542, or one or more layers comprising at least one of a layer 552, a layer 556, or a layer 558.

In some embodiments, the semiconductor device 500 comprises a set of bonding components 516 (e.g., a set of one or more bonding components) between the first die 508 and the semiconductor wafer 546. In some embodiments, the set of bonding components 516 comprises at least one of a bonding component 516a, a bonding component 516b, a bonding component 516c, or one or more other bonding components. In some embodiments, the semiconductor device 500 comprises a set of bonding components 520 (e.g., a set of one or more bonding components) between the second die 510 and the semiconductor wafer 546. In some embodiments, the set of bonding components 520 comprises at least one of a bonding component 520a, a bonding component 520b, a bonding component 520c, a bonding component 520d, or one or more other bonding components. In some embodiments, the semiconductor device 500 comprises a set of bonding components 524 (e.g., a set of one or more bonding components) between the third die 512 and the semiconductor wafer 546. In some embodiments, the set of bonding components 524 comprises at least one of a bonding component 524a, a bonding component 524b, a bonding component 524c, or one or more other bonding components.

In some embodiments, the semiconductor wafer 546 comprises a set of bonding components 526 (e.g., a set of one or more bonding components) joined with the set of bonding components 516. In some embodiments, the set of bonding components 526 comprises at least one of a bonding component 526a, a bonding component 526b, a bonding component 526c, or one or more other bonding components. In some embodiments, a connection (e.g., an electrical connection) is established between the first die 508 and the semiconductor wafer 546 via a pair of joined bonding components, such as at least one of bonding components 516a and 526a, bonding components 516b and 526b, or bonding components 516c and 526c.

In some embodiments, the semiconductor wafer 546 comprises a set of bonding components 528 (e.g., a set of one or more bonding components) joined with the set of bonding components 520. In some embodiments, the set of bonding components 528 comprises at least one of a bonding component 528a, a bonding component 528b, a bonding component 528c, a bonding component 528d, or one or more other bonding components. In some embodiments, a connection (e.g., an electrical connection) is established between the first die 508 and the semiconductor wafer 546 via a pair of joined bonding components, such as at least one of bonding components 520a and 528a, bonding components 520b and 528b, bonding components 520c and 528c, or bonding components 520d and 528d.

In some embodiments, the semiconductor wafer 546 comprises a set of bonding components 530 (e.g., a set of one or more bonding components) joined with the set of bonding components 524. In some embodiments, the set of bonding components 530 comprises at least one of a bonding component 530a, a bonding component 530b, a bonding component 530c, or one or more other bonding components. In some embodiments, a connection (e.g., an electrical connection) is established between the first die 508 and the semiconductor wafer 546 via a pair of joined bonding components, such as at least one of bonding components 524a and 530a, bonding components 524b and 530b, or bonding components 524c and 530c. In some embodiments, the semiconductor wafer 546 comprises a set of vias (e.g., a set of one or more vias). In some embodiments, each via of one, some, or all of the set of vias comprises a through-silicon via (TSV). In some embodiments, the set of vias comprises at least one of a via 532a, a via 532b, a via 532c, a via 532d, a via 532e, a via 532f, a via 532g, or a via 532h.

In some embodiments, one or more connections (e.g., electrical connections) between components (e.g., components inside and/or outside the semiconductor device 500) are established via at least one of the set of bonding components 516, the set of bonding components 520, the set of bonding components 524, the set of bonding components 526, the set of bonding components 528, the set of bonding components 530, or the set of vias. In some embodiments, the components comprise at least one of one or more transistors, one or more capacitors, one or more logic components, one or more processing components, one or more memory cells, etc.

In some embodiments, the semiconductor device 500 comprises a set of bonding components 560 (e.g., a set of one or more bonding components). In some embodiments, the set of bonding components 560 comprises at least one of a bonding component 560a, a bonding component 560b, a bonding component 560c, a bonding component 560d, or a bonding component 560e. In some embodiments, a size of the set of bonding components 560 is greater than at least one of a size of the set of bonding components 516, a size of the set of bonding components 520, a size of the set of bonding components 524, a size of the set of bonding components 526, a size of the set of bonding components 528, or a size of the set of bonding components 530. In some embodiments, the set of bonding components 560 is used to bond the semiconductor device 500 to a substrate to form a second semiconductor device comprising the semiconductor device 500 and the substrate. In some embodiments, the substrate comprises at least one of a silicon substrate or other type of substrate. In some embodiments, the second semiconductor device has a chip-on-wafer-on-substrate (CoWoS) arrangement.

In some embodiments, each bonding component of one, some or all bonding components of the set of bonding components 560 comprises at least one of a controller collapse chip connect (C4) bump or other suitable bump. In some embodiments, each bonding component of one, some or all bonding components has a bump size that is greater than a threshold bump size (e.g., 100 micrometers or other threshold bump size). In some embodiments, each bonding component of one, some or all bonding components of at least one of the set of bonding components 516, the set of bonding components 520, the set of bonding components 524, the set of bonding components 526, the set of bonding components 528, or the set of bonding components 530 comprises at least one of a microbump, a hybrid bond pad, etc. In some embodiments, each bonding component of one, some or all bonding components of at least one of the set of bonding components 516, the set of bonding components 520, the set of bonding components 524, the set of bonding components 526, the set of bonding components 528, or the set of bonding components 530 has a bump size that is less than the threshold bump size. In some embodiments, each bonding component of one, some or all bonding components of the present disclosure comprises at least one of copper, one or more other metals, or one or more other suitable materials.

In some embodiments, the first bonding process is performed as a stage of fabrication of the semiconductor device 500. In some embodiments, the first bonding process comprises at least one of a direct bonding process (e.g., a CoW direct bonding process), a fusion bonding process, or a hybrid bonding process. In some embodiments, at least one of the first oxide structure 534, the second oxide structure 534, the fourth die 544, or the set of bonding components 560 is formed after the first bonding process is performed. In some embodiments, the first item 108a comprises the semiconductor wafer 546. In some embodiments, the second item 108b comprises an item 502 comprising at least one of the first die 508 or the set of bonding components 516. In some embodiments, the third item 108c comprises an item 504 comprising at least one of the second die 510 or the set of bonding components 520. In some embodiments, the fourth item 108d comprises an item 506 comprising at least one of the third die 512 or the set of bonding components 524. In some embodiments, at least one of the first set of bonding components of the first item 108a comprises the set of bonding components 526, the second set of bonding components of the second item 108b comprises the set of bonding components 516, the third set of bonding components of the first item 108a comprises the set of bonding components 528, the fourth set of bonding components of the third item 108c comprises the set of bonding components 520, the fifth set of bonding components of the first item 108a comprises the set of bonding components 530, or the sixth set of bonding components of the fourth item 108d comprises the set of bonding components 524.

In some embodiments, the second bonding process is performed as a stage of fabrication of the semiconductor device 500. In some embodiments, the second bonding process comprises at least one of a direct bonding process (e.g., a CoW direct bonding process), a fusion bonding process, or a hybrid bonding process. In some embodiments, at least one of the first oxide structure 534, the second oxide structure 534, the fourth die 544, or the set of bonding components 560 is formed after the first bonding process is performed. In some embodiments, the fifth item 208a comprises the semiconductor wafer 546. In some embodiments, at least one of the sixth item 208b comprises the item 502, the seventh item 208c comprises the item 504, or the eighth item 208d comprises the item 506. In some embodiments, at least one of the seventh set of bonding components of the fifth item 208a comprises the set of bonding components 526, the eighth set of bonding components of the sixth item 208b comprises the set of bonding components 516, the ninth set of bonding components of the fifth item 208a comprises the set of bonding components 528, the tenth set of bonding components of the seventh item 208c comprises the set of bonding components 520, the eleventh set of bonding components of the fifth item 208a comprises the set of bonding components 530, or the twelfth set of bonding components of the eighth item 208d comprises the set of bonding components 524. In some embodiments, an item temperature threshold associated with at least one of the first die 508, the second die 510, or the third die 512 is less than an item temperature threshold associated with the semiconductor wafer 546, such as due, at least in part, a temperature sensitivity of at least one of circuitry, one or more electronic components, etc. of at least one of the first die 508, the second die 510, or the third die 512 being greater than a temperature sensitivity of at least one of circuitry, one or more electronic components, etc. of the semiconductor wafer 546. In some embodiments, performing the first cooling process prior to the second bonding process protects at least one of first die 508, the second die 510, or the third die 512 from being damaged during the second bonding process.

Embodiments are contemplated in which at least a portion of the cooling channel of the liquid cooling module 102 through which a liquid (e.g., cooled liquid) is circulated to cool the second platform 106 is inside the second platform 106 or in direct contact with the second platform 106. In some embodiments, the cooling channel is defined by a second conduit disposed in the second platform 106. In some embodiments, the second conduit has one, some, or all of the characteristics, features, shapes, and/or configurations provided herein with respect to the conduit 316.

Embodiments are contemplated in which the liquid cooling module 102 is used to cool the first platform 110, such as using one or more of the techniques provided herein with respect to using the liquid cooling module 102 to cool the second platform 106.

In some embodiments, each conduit of one, some or all conduits of the present disclosure comprises at least one of one or more pipes, one or more tubes, etc. for conducting a liquid.

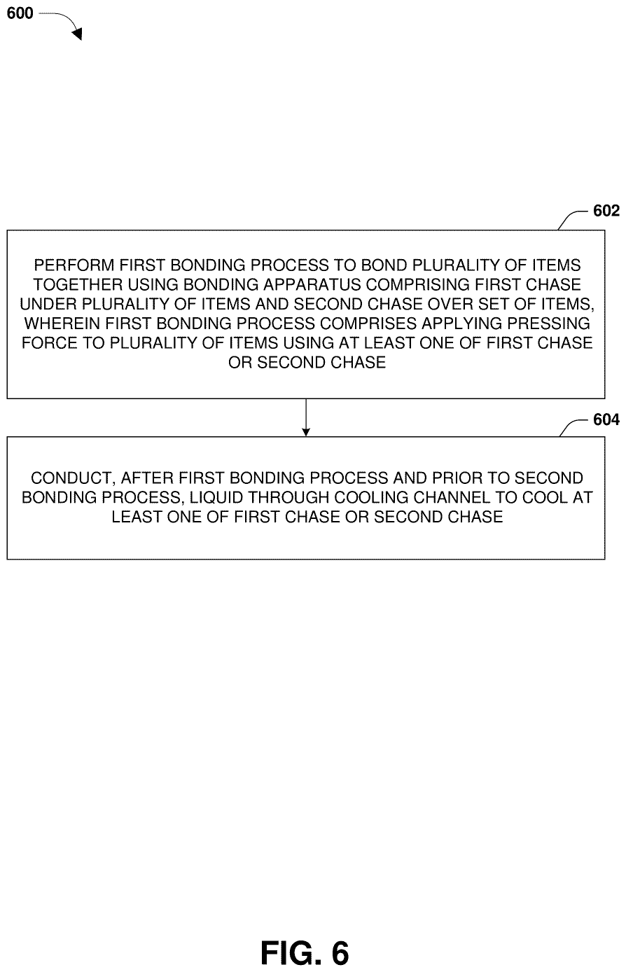

A method 600 is illustrated in FIG. 6 in accordance with some embodiments. At 602, a first bonding process to bond a plurality of items (e.g., the first plurality of items 108) together is performed using a bonding apparatus (e.g., the apparatus 100) including a first platform (e.g., the first platform 110) under the plurality of items and a second platform (e.g., the second platform 106) over the plurality of items. The first bonding process includes applying a pressing force to the plurality of items using at least one of the first platform or the second platform. At 604, after the first bonding process and prior to a second bonding process, a liquid is conducted through a cooling channel (e.g., the cooling channel defined by the conduit 316) to cool at least one of the first platform or the second platform.

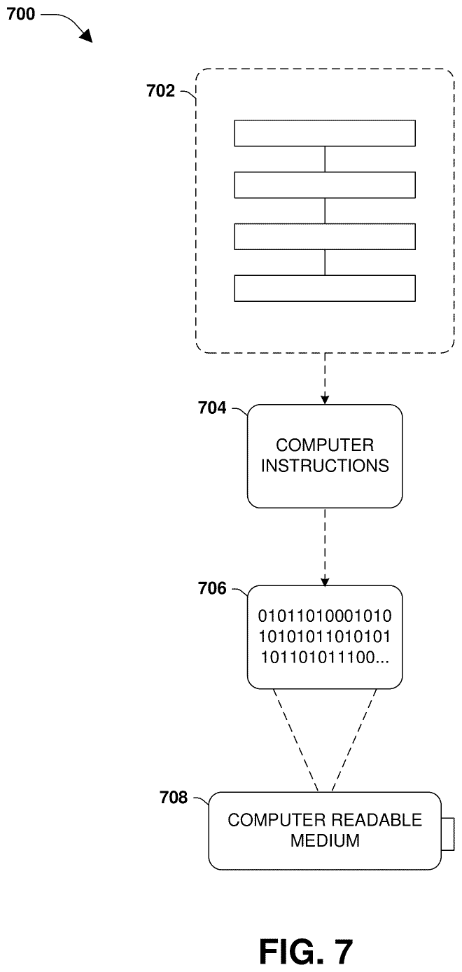

One or more embodiments involve a computer-readable medium comprising processor-executable instructions configured to implement one or more of the techniques presented herein. An exemplary computer-readable medium is illustrated in FIG. 7, wherein the embodiment 700 comprises a computer-readable medium 708 (e.g., a CD-R, DVD-R, flash drive, a platter of a hard disk drive, etc.), on which is encoded computer-readable data 706. This computer-readable data 706 in turn comprises a set of processor-executable computer instructions 704 configured to implement one or more of the principles set forth herein when executed by a processor. In some embodiments 700, the processor-executable computer instructions 704 are configured to implement a method 702, such as at least some of the aforementioned method(s) when executed by a processor. In some embodiments, the processor-executable computer instructions 704 are configured to implement a system, such as at least some of the one or more aforementioned systems when executed by a processor. In some embodiments, the processor-executable computer instructions 704 are configured to implement an apparatus, such as at least some of the one or more aforementioned apparatuses when executed by a processor. Many such computer-readable media may be devised by those of ordinary skill in the art that are configured to operate in accordance with the techniques presented herein.

In some embodiments, an apparatus is provided. The apparatus includes a first platform configured to support a plurality of items to be bonded together in a first bonding process. The apparatus includes a second platform over the plurality of items. At least one of the first platform or the second platform is configured to apply a pressing force to the plurality of items during the first bonding process. The apparatus includes a liquid cooling module configured to conduct, after the first bonding process and prior to a second bonding process, a liquid through a cooling channel to cool the second platform.

In some embodiments, a method is provided. The method includes performing a first bonding process to bond a plurality of items together using a bonding apparatus including a first platform under the plurality of items and a second platform over the plurality of items, wherein the first bonding process includes applying a pressing force to the plurality of items using at least one of the first platform or the second platform. The method includes conducting, after the first bonding process and prior to a second bonding process, a liquid through a cooling channel to cool at least one of the first platform or the second platform.

In some embodiments, an apparatus is provided. The apparatus includes a first platform configured to support a plurality of items to be bonded together in a bonding process. The apparatus includes a second platform over the plurality of items. At least one of the first platform or the second platform is configured to apply a pressing force to the plurality of items during the bonding process. The apparatus includes a liquid cooling module configured to conduct, after the bonding process, a liquid through a cooling channel to cool at least one of the first platform or the second platform.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that Yeah illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally to be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

1. An apparatus, comprising:
a first platform configured to support a plurality of items to be bonded together in a first bonding process;
a second platform over the plurality of items, wherein at least one of the first platform or the second platform is configured to apply a pressing force to the plurality of items during the first bonding process; and
a liquid cooling module comprising a cooling channel housing disposed over an uppermost surface of the second platform and configured to conduct, after the first bonding process and prior to a second bonding process, a liquid through a cooling channel defined within the cooling channel housing to cool the second platform.

2. The apparatus of claim 1, comprising:
a heater configured to apply thermal energy to the first platform, wherein the first platform and the second platform are disposed between the heater and the liquid cooling module.

3. The apparatus of claim 1, wherein:
the cooling channel is arranged asymmetrically along a plane that is parallel or about parallel to the uppermost a surface of the second platform.

4. The apparatus of claim 1, comprising:
a thermal interface layer between the cooling channel and the second platform.

5. The apparatus of claim 4, wherein:
the cooling channel is arranged asymmetrically along a plane that is parallel or about parallel to a surface of the thermal interface layer.

6. The apparatus of claim 1, wherein the plurality of items comprises:
a semiconductor wafer.

7. The apparatus of claim 6, wherein the plurality of items comprises:
a die over the semiconductor wafer.

8. The apparatus of claim 7, wherein:
a first item temperature threshold associated with the die is less than a second item temperature threshold associated with the semiconductor wafer.

9.-12. (canceled)

13. An apparatus, comprising:
a first platform configured to support a plurality of items to be bonded together in a bonding process;
a second platform over the plurality of items, wherein at least one of the first platform or the second platform is configured to apply a pressing force to the plurality of items during the bonding process; and
a liquid cooling module configured to conduct, after the bonding process, a liquid through a cooling channel disposed within the liquid cooling module to cool the second platform, wherein the second platform is disposed between the plurality of items and the liquid cooling module.

14. The apparatus of claim 13, comprising:
a heater configured to apply thermal energy to the first platform, wherein the first platform is disposed between the heater and the plurality of items.

15. The apparatus of claim 13, wherein:
the cooling channel is arranged asymmetrically along a plane that is parallel or about parallel to a surface of the second platform.

16. The apparatus of claim 13, comprising:
a thermal interface layer configured to transfer thermal energy from the second platform to the liquid cooling module.

17. The apparatus of claim 16, wherein:
the cooling channel is arranged asymmetrically along a plane that is parallel or about parallel to a surface of the thermal interface layer.

18. The apparatus of claim 13, wherein the plurality of items comprises:
a semiconductor wafer.

19. The apparatus of claim 18, wherein the plurality of items comprises:
a die over the semiconductor wafer.

20. The apparatus of claim 19, wherein:
a first item temperature threshold associated with the die is less than a second item temperature threshold associated with the semiconductor wafer.

21. An apparatus, comprising:
a first platform configured to apply a pressing force to a semiconductor wafer during a first bonding process to bond one or more items to the semiconductor wafer; and
a liquid cooling module over the first platform and comprising a cooling channel having at least three concentric, arc-shaped sections between an inlet and an outlet, wherein a central angle of an innermost concentric, arc-shaped section of the at least three concentric, arc-shaped sections is more than 180 degrees.

22. The apparatus of claim 21, comprising:
a thermal interface layer between the first platform and the liquid cooling module to transfer thermal energy between the liquid cooling module and the first platform.

23. The apparatus of claim 21, comprising:
a heater under the first platform.

24. The apparatus of claim 23, comprising:
a second platform between the heater and the first platform.
